(19) United States
(12) Patent Application Publication
(10) Pub. No.: US 2023/0352519 A1
(43) Pub. Date: Nov. 2, 2023

(54) SEMICONDUCTOR STRUCTURES AND FABRICATION METHODS OF SEMICONDUCTOR STRUCTURES

(71) Applicant: Semiconductor Manufacturing International (Shanghai) Corporation, Shanghai (CN)

(72) Inventors: Xiaodong WANG, Shanghai (CN); Yichao WU, Shanghai (CN); Weihong QIAN, Shanghai (CN); Xining WANG, Shanghai (CN); Xiaolin WANG, Shanghai (CN)

(21) Appl. No.: 18/117,911

(22) Filed: Mar. 6, 2023

(30) Foreign Application Priority Data
Apr. 29, 2022 (CN) 202210468722.4

(51) Int. Cl. H01L 21/02

(52) U.S. Cl. CPC H01L 28/92

(57) ABSTRACT

A semiconductor structure includes a substrate, a bottom metal structure located on the substrate, a first dielectric layer located on the bottom metal structure, first plug structures, second plug structures, and first metal structures. The substrate includes a base, a device structure located on the base, and conductive layers located on the device structure. The bottom metal structure is electrically connected to the conductive layers. The first dielectric layer includes a first opening structure and a second opening structure. The first opening structure includes first grooves and second grooves on top of the first grooves, and the second opening structure includes third grooves and fourth grooves on top of the third grooves. The first plug structures are located in the first grooves, and the second plug structures are located in the third grooves. The first metal structures are located in the second grooves and the fourth grooves.

### CROSS-REFERENCES TO RELATED APPLICATIONS

This application claims the priority of Chinese Patent Application No. CN202210468722.4, filed on Apr. 29, 2022, the entire content of which is incorporated herein by reference.

### FIELD OF THE DISCLOSURE

The present disclosure generally relates to the field of semiconductor fabrication technology and, more particularly, relates to semiconductor structures and fabrication methods of semiconductor structures.

### BACKGROUND

Metal-oxide-metal (MOM) capacitors are metal-dielectric-metal capacitor structures, which are commonly used in integrated circuits. In existing technologies, upper and lower electrodes of the MOM capacitors usually include metal strips with flat surfaces, which are interspersed in a one-dimensional or two-dimensional manner. However, in order to improve component integration, continuous research and development are needed in industry so that capacitive components with higher capacitance density and capacitance storage can be fabricated in limited spaces.

### BRIEF SUMMARY OF THE DISCLOSURE

One aspect of the present disclosure provides a semiconductor structure. The semiconductor structure includes a substrate, a bottom metal structure located on the substrate, a first dielectric layer located on the bottom metal structure, a first opening structure located in the first dielectric layer including first grooves and second grooves on top of the first grooves, a second opening structure located in the first dielectric layer including third grooves and fourth grooves on top of the third grooves, first plug structures located in the first grooves, second plug structures located in the third grooves, and first metal structures located in the second grooves and the fourth grooves. The substrate includes a base, a device structure located on the base, and conductive layers located on the device structure. The bottom metal structure is electrically connected to the conductive layers. An extension direction of the first opening structure is parallel to an extension direction of the bottom metal structure, projections of the first grooves on the substrate are located within projections of the second grooves on the substrate, and bottoms of the first grooves expose surface of the first dielectric layer. Projections of the third grooves on the substrate are located within projections of the fourth grooves on the substrate, the third grooves expose top surface of the bottom metal structure, and depths of the first grooves are smaller than depths of the third grooves.

Another aspect of the present disclosure provides a method for fabricating a semiconductor structure. The method includes providing a substrate, forming a bottom metal structure located on the substrate, forming a first dielectric layer located on the bottom metal structure, forming a first opening structure located in the first dielectric layer including first grooves and second grooves on top of the first grooves, forming a second opening structure located in the first dielectric layer including third grooves and fourth grooves on top of the third grooves, forming first plug structures located in the first grooves, forming second plug structures located in the third grooves, and forming first metal structures located in the second grooves and the fourth grooves. The substrate includes a base, a device structure located on the base, and conductive layers located on the device structure. The bottom metal structure is electrically connected to the conductive layers. An extension direction of the first opening structure is parallel to an extension direction of the bottom metal structure, projections of the first grooves on the substrate are located within projections of the second grooves on the substrate, and bottoms of the first grooves expose surface of the first dielectric layer. Projections of the third grooves on the substrate are located within projections of the fourth grooves on the substrate, the third grooves expose top surface of the bottom metal structure, and depths of the first grooves are smaller than depths of the third grooves.

Other aspects of the present disclosure can be understood by those skilled in the art in light of the description, the claims, and the drawings of the present disclosure.

### BRIEF DESCRIPTION OF THE DRAWINGS

FIGS. 1-3 illustrate schematic views of an exemplary semiconductor structure consistent with various disclosed embodiments in the present disclosure.

FIGS. 4-18 illustrate schematic views of semiconductor structures at certain stages during a fabrication process of an exemplary semiconductor structure consistent with various disclosed embodiments in the present disclosure.

FIG. 19 illustrates a schematic view of another exemplary semiconductor structure consistent with various disclosed embodiments in the present disclosure.

FIG. 20 illustrates a flowchart of an exemplary method for fabricating a semiconductor structure consistent with various disclosed embodiments in the present disclosure.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

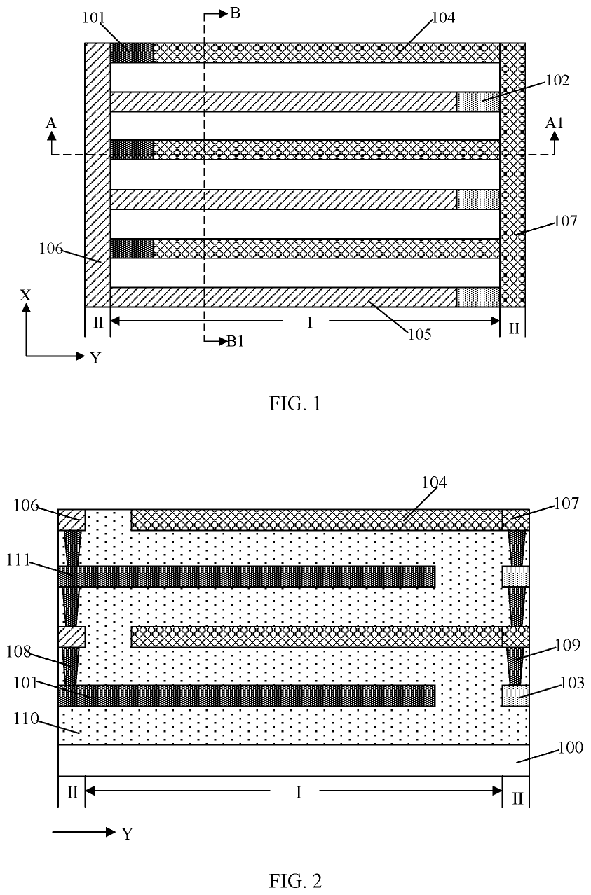

FIGS. 1-3 illustrate schematic views of an exemplary semiconductor structure consistent with various disclosed embodiments in the present disclosure.

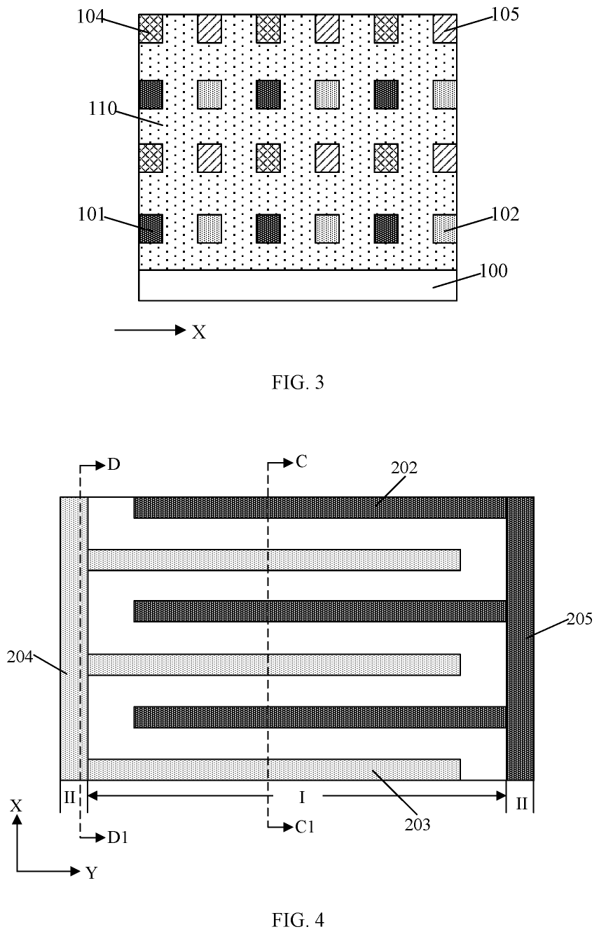

FIG. 1 shows a top view of FIGS. 2 and 3 without dielectric structures, FIG. 2 shows a schematic cross-section view of FIG. 1 along section line AA1, and FIG. 3 shows a schematic cross-section view of FIG. 1 along section line BB 1. The semiconductor structure includes a substrate 100, and first metal structures and second metal structures on the substrate 100. The substrate 100 includes a first region I and second regions II located at two sides of the first region I. The first metal structures and the second metal structures are alternately stacked in a direction perpendicular to surface of the substrate 100. The first metal structures include a plurality of first metal layers 101 and a plurality of second metal layers 102 located on the first region I, and first conductive layers 111 and second conductive layers 103 respectively located on the second regions II at two sides of the first region I. The plurality of the first metal layers 101 and the plurality of the second metal layers 102 are alternately arranged in parallel along a first direction X parallel to the surface of the substrate 100. The first conductive layers 111 and the second conductive layers 103 are parallel to the first direction X. The plurality of the second metal layers 102 are connected to the second conductive layers 103, and the plurality of the first metal layers 101 are connected to the first conductive layers 111. There are spacings between the first metal layers 101 and the second conductive layers 103, and there are spacings between the second metal layers 102 and the first conductive layers 111. The second metal structures include a plurality of third metal layers 104 on the first metal layers 101, a plurality of fourth metal layers 105 on the second metal layers 102, third conductive layers 106 on the first conductive layers 111, and fourth conductive layers 107 on the second conductive layers 103. The third metal layers 104 and the fourth metal layers 105 are alternately arranged in parallel along the first direction X. The third conductive layers 106 and the fourth conductive layers 107 are parallel to the first direction X. The plurality of the fourth metal layers 105 are connected to the third conductive layers 106, and the plurality of the third metal layers 104 are connected to the fourth conductive layers 107. There are spacings between the third metal layers 104 and the third conductive layers 106, and there are spacings between the fourth metal layers 105 and the fourth conductive layers 107.

The semiconductor structure also includes first plugs 108 on the first conductive layers 111, second plugs 109 on the second conductive layers 103, and dielectric structures 110 on the substrate 100. The third metal layers 104 are electrically connected to the second metal layers 102 through the second plugs 109, the fourth metal layers 105 are electrically connected to the first metal layers 101 through the first plugs 108. The first metal structures, the second metal structures, the first plugs 108, and the second plugs 109 are located in the dielectric structures 110.

In the semiconductor structure, a plurality layers of the first metal structures and the second metal structures are used as capacitors. Capacitance types of the semiconductor structure include first type capacitances, second type capacitances, and third type capacitances. The first type capacitances include capacitances between adjacent first metal layers 101 and second metal layers 102 in the first metal structures of the same layer, and capacitances between adjacent third metal layers 104 and fourth metal layer 105 in the second metal structures of the same layer. The second type capacitances include capacitances between two adjacent layers of the first metal structures, and capacitances between two adjacent layers of the second metal structures. The third type capacitances include capacitances between two metal structures separated by at least one layer of metal structures, and the metal structures include the first metal structures and the second metal structures. The larger the first type capacitances, the second type capacitances, and the third type capacitances, the larger a total capacitance of the semiconductor structure, and the stronger a storage capacity of the semiconductor structure as a capacitor. With existing process nodes, size of the semiconductor structure has reached a small level, and a charge storage capability of the semiconductor structure needs to be improved to meet requirements of high-performance semiconductor devices.

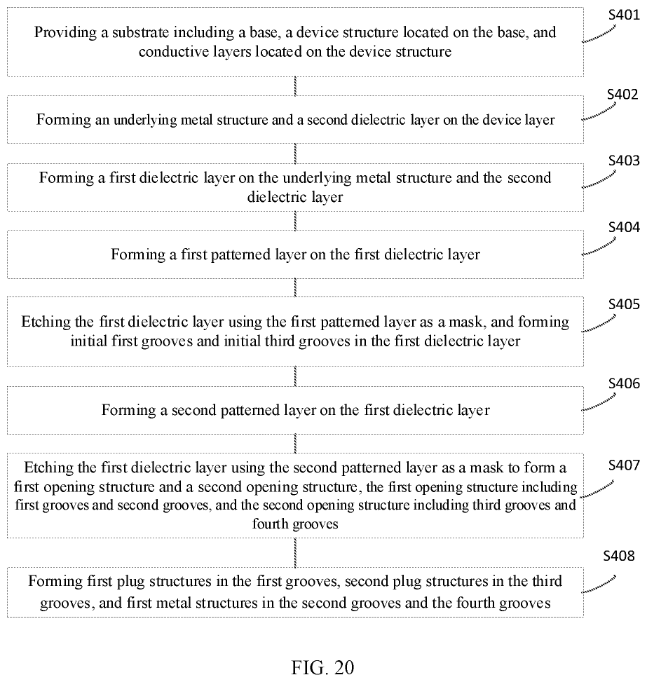

The present disclosure provides a semiconductor structure and a fabrication method of the semiconductor structure. FIG. 20 illustrates a flowchart of an exemplary method for fabricating a semiconductor structure consistent with various disclosed embodiments in the present disclosure. FIGS. 4-18 illustrate schematic views of semiconductor structures at certain stages of the exemplary fabrication process.

Referring to FIG. 20, at the beginning of the fabrication process, a substrate is provided (S401). FIGS. 4-6 show schematic views of a corresponding semiconductor structure.

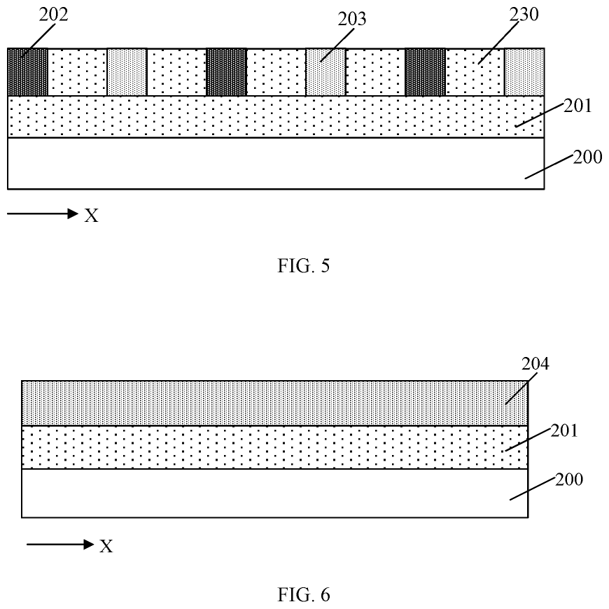

FIG. 4 shows a top view of FIGS. 5 and 6 without a second dielectric layer 230, FIG. 5 shows a schematic cross-section view of FIG. 4 along section line CC1, and FIG. 6 shows a schematic cross-section view of FIG. 4 along section line DD1. A substrate 200 is provided, and the substrate 200 includes a first region I and second regions II located at two sides of the first region I.

In some embodiments, there is a device layer 201 on the substrate 200 and a conductive layer (not shown) on the device layer 201. The device layer 201 includes an isolation structure (not shown) and a device structure (not shown) located inside the isolation structure. The device structure includes transistors, diodes, triodes, capacitors, inductors, conductive structures, etc.

In some embodiments, material of the substrate 200 is silicon.

In some other embodiments, the material of the substrate includes silicon carbide, silicon germanium, a multi-component semiconductor material including group III-V elements, silicon-on-insulator (SOI), and/or germanium-on-insulator (GOI), where the group III-V elements used for the multi-component semiconductor material include InP, GaAs, GaP, InAs, InSb, InGaAs, or InGaAsP.

Further, returning to FIG. 20, a bottom metal structure and the second dielectric layer 230 are formed on the device layer 201 (S402). FIGS. 4-6 show the schematic views of the corresponding semiconductor structure.

Referring back to FIGS. 4-6, the bottom metal structure is located in the second dielectric layer 230, and is electrically connected to the conductive layer.

The bottom metal structure includes a plurality of first metal layers 202 and a plurality of second metal layers 203 located on the first region I, and a first conductive layer 205 and a second conductive layer 204 respectively located on the second regions II at two sides of the first region I. The plurality of the first metal layers 202 and the plurality of the second metal layers 203 are alternately arranged in parallel along a first direction X parallel to surface of the substrate 200. The first conductive layer 205 and the second conductive layer 204 are parallel to the first direction X. The plurality of the first metal layers 202 are connected to the first conductive layer 205, and the plurality of the second metal layers 203 are connected to the second conductive layer 204. There are spacings between the first metal layers 202 and the second conductive layer 204, and there are spacings between the second metal layers 203 and the first conductive layer 205.

In some embodiments, the bottom metal structure is electrically connected to the device structure in the device layer 201.

Material of the bottom metal structure includes metal or metal nitride. The metal includes a combination of one or more of copper, aluminum, tungsten, cobalt, nickel, and tantalum. The metal nitride includes a combination of one or more of tantalum nitride and titanium nitride.

Material of the second dielectric layer 230 includes a dielectric material including a combination of one or more of silicon oxide, silicon nitride, silicon carbide, silicon oxycarbide, silicon oxynitride, aluminum oxide, aluminum nitride, silicon nitride carbide, and nitrogen silicon oxycarbide. In some embodiments, the material of the second dielectric layer 230 includes silicon oxide.

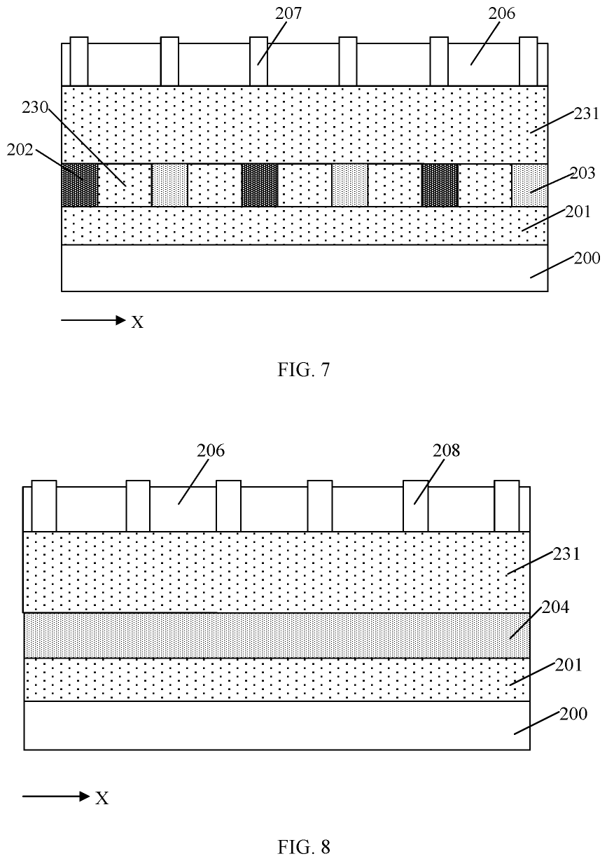

Further, returning to FIG. 20, a first dielectric layer 231 is formed on the bottom metal structure and the second dielectric layer 230 (S403). FIGS. 7 and 8 show schematic cross-section views of a corresponding semiconductor structure. FIG. 7 is a schematic structural diagram based on FIG. 5, and FIG. 8 is a structural schematic diagram based on FIG. 6.

Material of the first dielectric layer 231 includes a dielectric material including a combination of one or more of silicon oxide, silicon nitride, silicon carbide, silicon oxycarbide, silicon oxynitride, aluminum oxide, aluminum nitride, silicon nitride carbide, and nitrogen silicon oxycarbide. In some embodiments, the material of the first dielectric layer 231 includes silicon oxide.

Further, a first opening structure and a second opening structure are formed in the first dielectric layer 231 on the bottom metal structure.

In some embodiments, the first opening structure and the second opening structure are formed simultaneously. For the formation process of the first opening structure and the second opening structure, reference can be made to FIGS. 7-14.

Further, returning to FIG. 20, a first patterned layer 206 is formed on the first dielectric layer 231 (S404). FIGS. 7 and 8 show the schematic cross-section views of the corresponding semiconductor structure.

Referring to FIGS. 7 and 8 again, there are a plurality of third openings 208 and fourth openings 207 in the first patterned layer 206. Extension directions of the fourth openings 207 are parallel to a second direction Y, where the second direction Y is parallel to the surface of the substrate 200 and is perpendicular to the first direction X. Sizes of the fourth openings 207 in the first direction X are smaller than sizes of the third openings 208 in the first direction X and the second direction Y.

The sizes of the fourth openings 207 in the first direction X are smaller than the sizes of the third openings 208 in the first direction X and the second direction Y, so that when further the first dielectric layer 231 is etched using the first patterned layer 206 as a mask, and initial first grooves and initial third grooves are formed in the first dielectric layer 231, depths of the formed initial first grooves are smaller than depths of the initial third grooves.

In some embodiments, the sizes of the fourth openings 207 in the first direction X are 30% to 70% of the sizes of the third openings 208 in the first direction X and the second direction Y.

In some embodiments, material of the first patterned layer 206 includes photoresist.

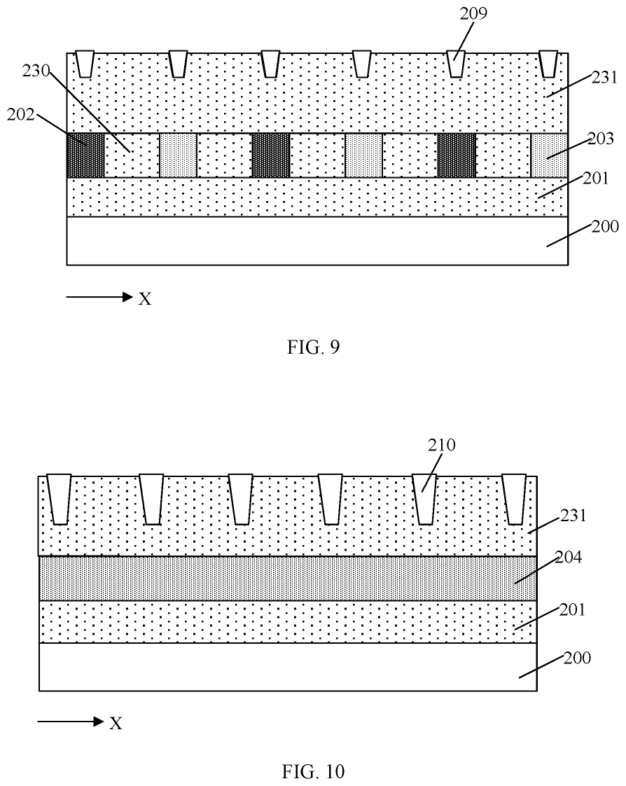

Further, returning to FIG. 20, the first dielectric layer 231 is etched using the first patterned layer 206 as a mask, and initial first grooves 209 and initial third grooves 210 are formed in the first dielectric layer 231 (S405). FIGS. 9 and 10 show schematic cross-section views of a corresponding semiconductor structure. FIG. 9 is a schematic structural diagram based on FIG. 7, and FIG. 10 is a structural schematic diagram based on FIG. 8.

Referring to FIGS. 9 and 10, depths of the initial first grooves 209 are smaller than depths of the initial third grooves 210, so that when further the first dielectric layer 231 is etched using the first patterned layer as a mask to form the first opening structure and the second opening structure, depths of the first grooves of the first opening structure are smaller than depths of the third grooves of the second opening structure. Therefore, the first grooves are prevented from exposing surface of the bottom metal structure, and further first plug structures formed in the first grooves and the bottom metal structure are prevented from being short-circuited.

A process of etching the first dielectric layer 231 using the first patterned layer 206 as a mask includes a dry etching process.

Since the sizes of the fourth openings 207 in the first direction X are smaller than the sizes of the third openings 208 in the first direction X and the second direction Y, when the first dielectric layer 231 is etched using the first patterned layer 206 as a mask, process gas of the dry etching process enters the fourth openings 207 with less gas, so that an etching rate of the first dielectric layer 231 exposed by the fourth openings 207 is lower than an etching rate of the first dielectric layer 231 exposed by the third openings 208 in the dry etching process.

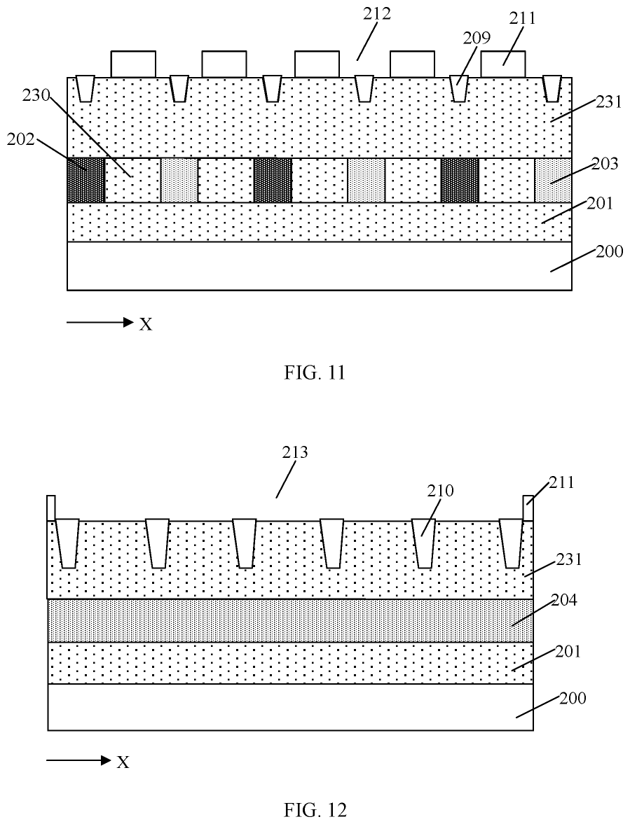

Further, returning to FIG. 20, a second patterned layer 211 is formed on the first dielectric layer 231 (S406). FIGS. 11 and 12 show schematic cross-section views of a corresponding semiconductor structure. FIG. 11 is a schematic structural diagram based on FIG. 9, and FIG. 12 is a structural schematic diagram based on FIG. 10.

Referring to FIGS. 11 and 12, there are fifth openings 213 and sixth openings 212 in the second patterned layer 211. The fifth openings 213 expose top surfaces of the initial third grooves 210 and part of surface of the first dielectric layer 231, and extension directions of the fifth openings 213 are parallel to the first direction X. The sixth openings 212 expose top surfaces of the initial first grooves 209 and part of the surface of the first dielectric layer 231, and extension directions of the sixth openings 212 are parallel to the second direction Y.

In some embodiments, material of the second patterned layer 211 includes photoresist.

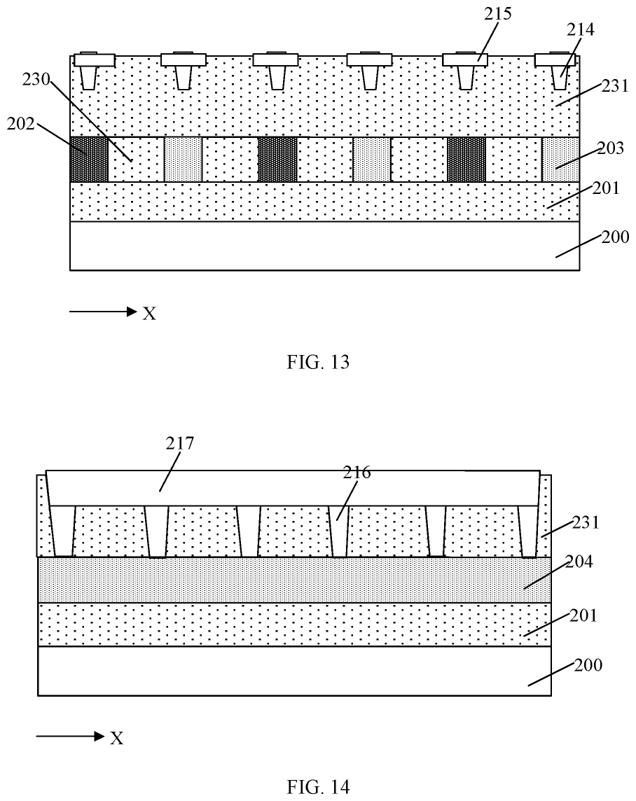

Further, returning to FIG. 20, the first dielectric layer 231 is etched using the second patterned layer 211 as a mask to form the first opening structure and the second opening structure (S407). FIGS. 13 and 14 show schematic cross-section views of a corresponding semiconductor structure. FIG. 13 is a schematic structural diagram based on FIG. 11, and FIG. 14 is a structural schematic diagram based on FIG. 12.

Referring to FIGS. 13 and 14, the first opening structure includes first grooves 214 and second grooves 215 located at top of the first grooves 214, and the second opening structure includes third grooves 216 and fourth grooves 217 located at top of the third grooves 216. Bottoms of the first grooves 214 expose the surface of the first dielectric layer 231, and the third grooves 216 expose top surface of the bottom metal structure.

In some embodiments, the third grooves 216 expose top surface of the second conductive layer 204.

The first opening structure and the second opening structure are both Damascus structures. Top opening of the Damascus structure is relatively large, which facilitates further filling of metal materials.

In some embodiments, the depths of the first grooves 214 are smaller than the depths of the third grooves 216, so that the first plug structures further formed in the first grooves 214 can be electrically isolated from the bottom metal structure.

In some embodiments, the depths of the first grooves 214 are 20% to 80% of the depths of the third grooves 216, so that when the first plug structures are further formed in the first grooves 214, spacings between the first plug structures and the bottom metal structure can be reduced. Therefore, the spacings are not so large that an effect of increasing capacitance is not obvious, and the spacings are not so small that a short circuit is likely to occur.

In some embodiments, sizes of the first grooves 214 in the second direction Y are smaller than sizes of the second grooves 215 in the second direction Y, so that a short circuit caused by contact between the first plug structures further formed in the first grooves 214 and the second plug structures can be avoided.

Projected images of the third grooves 216 on the substrate 200 include rectangles.

In some embodiments, the projected images of the third grooves 216 on the substrate 200 are squares.

In some embodiments, the sizes of the first grooves 214 in the first direction X are smaller than side lengths of the projected images of the third grooves 216, so that the first grooves 214 formed by two etchings will not expose the bottom metal structure, while the third grooves 216 formed by two etchings will expose the bottom metal structure. Therefore, the first plug structures further formed in the first grooves 214 will not be short-circuited with the bottom metal structure, while the second plug structures further formed in the third grooves 216 can be in contact with the bottom metal structure for electrical connection.

In some embodiments, a process of etching the first dielectric layer 231 using the second patterned layer 211 as a mask includes a dry etching process. The dry etching process also etches the first dielectric layer 231 at the bottom of the initial first grooves 209 and the initial third grooves 210.

In some embodiments, extension directions of the fourth grooves 217 are parallel to the first direction X.

In some embodiments, depths of the second grooves 215 and the fourth grooves 217 are the same.

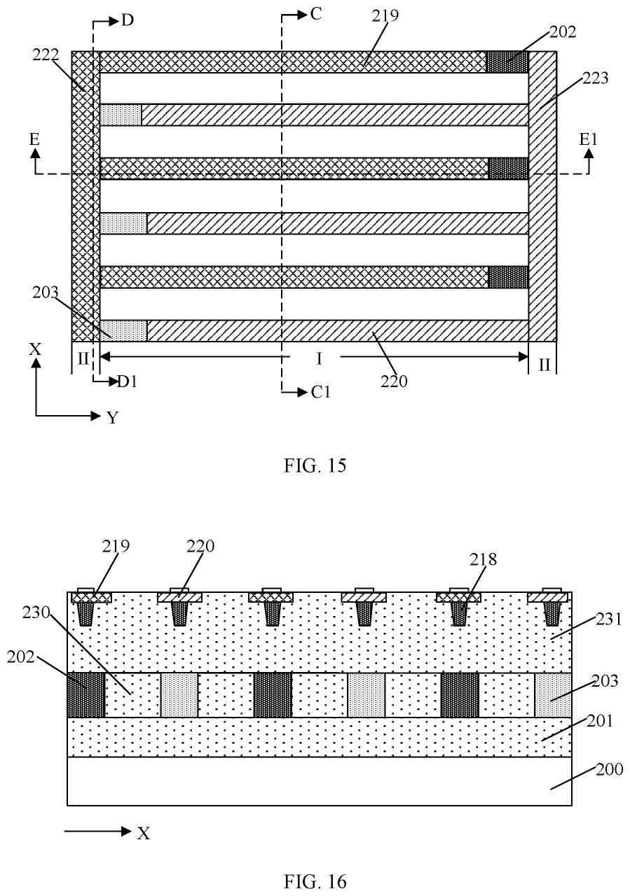

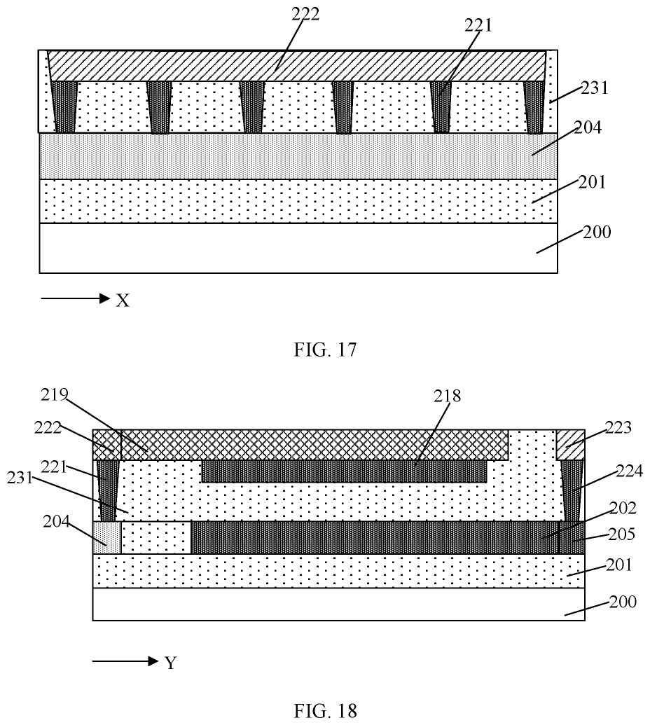

Further, returning to FIG. 20, first plug structures 218 are formed in the first grooves 214, the second plug structures are formed in the third grooves 216, and the first metal structures are formed in the second grooves 215 and the fourth grooves 217 (S408). FIGS. 15-18 show schematic views of a corresponding semiconductor structure. FIG. 15 shows a top view of FIGS. 16-18 without the first dielectric layer 231, FIG. 16 shows a schematic cross-section view of FIG. 15 along section line CC1, FIG. 17 shows a schematic cross-section view of FIG. 15 along section line DD1, and FIG. 18 shows a schematic cross-section view of FIG. 15 along section line EE1.

In some embodiments, the first plug structures 218, the second plug structures, and the first metal structures are formed simultaneously, so that a formation process of the first plug structures 218 does not need additional process flow, which can save process cost.

A method for fabricating the first plug structures 218, the second plug structures, and the first metal structures includes: forming a metal material layer (not shown) in the first grooves 214, the second grooves 215, the third grooves 216, the fourth grooves 217, and on the first dielectric layer 231; planarizing the metal material layer until top surface of the first dielectric layer 231 is exposed to form the first plug structures 218, the second plug structures, and the first metal structures. In some embodiments, the second plug structures include first plugs 224 located on the first conductive layer 205 and second plugs 221 located on the second conductive layer 204.

In some embodiments, the first metal structures include third metal layers 219 and fourth metal layers 220 respectively located in a plurality of the second grooves 215, and third conductive layers 223 and fourth conductive layers 222 respectively located in a plurality of the fourth grooves 217. The third metal layers 219 are located on the first metal layers 202, and the fourth metal layers 220 are located on the second metal layers 203. The third conductive layers 223 are located on the first conductive layer 205, and the fourth conductive layers 222 are located on the second conductive layer 204. A plurality of the fourth metal layers 220 are connected to the third conductive layers 223, and a plurality of the third metal layers 219 are connected to the fourth conductive layers 222. There are spacings between the third metal layers 219 and the third conductive layers 223, and there are spacings between the fourth metal layers 220 and the fourth conductive layers 222.

In some embodiments, the third metal layers 219 are electrically connected to the second metal layers 203 through the fourth conductive layers 222, the second plugs 221, and the second conductive layer 204. The fourth metal layers 220 are electrically connected to the first metal layers 202 through the third conductive layers 223, the first plugs 224, and the first conductive layer 205.

In some embodiments, the depths of the first grooves 214 are smaller than the depths of the third grooves 216, so that depths of the first plug structures 218 are smaller than depths of the first plugs 224 and the second plugs 221.

Materials of the first plug structures 218, the second plug structures, and the first metal structures include metal or metal nitride. The metal includes a combination of one or more of copper, aluminum, tungsten, cobalt, nickel, and tantalum. The metal nitride includes a combination of one or more of tantalum nitride and titanium nitride.

In some embodiments, projections of the third metal layers 219 on the substrate 200 partially coincide with projections of the first metal layers 202 on the substrate 200, and projections of the fourth metal layers 220 on the substrate 200 partially coincide with projections of the second metal layers 203 on the substrate 200.

As such, the formed semiconductor structure has the first plug structures 218 at the bottom of the third metal layers 219 and the fourth metal layers 220. On one hand, the first plug structures 218 reduce spacings between the first metal structures and the bottom metal structure, so that capacitances between the first metal structures and the bottom metal structure increase. On another hand, an overall cross-sectional area of the first plug structures 218 and the third metal layers 219 is increased, and an overall cross-sectional area of the first plug structures 218 and the fourth metal layers 220 is increased, so that capacitance between the third metal layer 219 and the fourth metal layer 220 of the same layer increases, thereby an overall capacitance of the semiconductor structure increases. On another hand, the formation process of the first plug structures 218 is adapted to formation process of the second plug structures and the first metal structures, and no additional process flow is needed.

Referring to FIGS. 15-18 again, the present disclosure further provides a semiconductor structure, which includes the substrate 200, the bottom metal structure on the substrate 200, the first dielectric layer 231 on the bottom metal structure, the first opening structure located in the first dielectric layer 231 including the first grooves and the second grooves on top of the first grooves, the second opening structure located in the first dielectric layer 231 including the third grooves and the fourth grooves on top of the third grooves, the first plug structures 218 located in the first grooves, the second plug structures in the third grooves, and the first metal structures in the second grooves and the fourth grooves. The substrate 200 includes a base, the device structure on the base, and the conductive layers on the device structure. The bottom metal structure is electrically connected to the conductive layers. Extension direction of the first opening structure is parallel to extension direction of the bottom metal structure. Projections of the first grooves on the substrate 200 are located within projections of the second grooves on the substrate 200. The bottoms of the first grooves expose the surface of the first dielectric layer. Projections of the third grooves on the substrate 200 are located within projections of the fourth grooves on the substrate 200. The third grooves expose the top surface of the bottom metal structure. The depths of the first grooves are smaller than the depths of the third grooves.

In some embodiments, the substrate 200 includes the first region I and the second regions II located at two sides of the first region I. The bottom metal structure includes the plurality of the first metal layers 202 and the plurality of the second metal layers 203 located on the first region I, and the first conductive layer 205 and the second conductive layer 204 respectively located on the second regions II at two sides of the first region I. The plurality of the first metal layers 202 and the plurality of the second metal layers 203 are alternately arranged in parallel along the first direction X parallel to the surface of the substrate 200. The first conductive layer 205 and the second conductive layer 204 are parallel to the first direction X. The plurality of the first metal layers 202 are connected to the first conductive layer 205, and the plurality of the second metal layers 203 are connected to the second conductive layer 204. There are spacings between the first metal layers 202 and the second conductive layer 204, and there are spacings between the second metal layers 203 and the first conductive layer 205. The extension direction of the first opening structure is parallel to extension directions of the first metal layers 202 and the second metal layers 203. The third grooves expose top surfaces of the second conductive layer 204 and the first conductive layer 205.

In some embodiments, the first opening structure is in a portion of the first dielectric layer 231 that is on the first metal layers 202 and the second metal layers 203. The second opening structure is in a portion of the first dielectric layer 231 that is on the first conductive layer 205 and the second conductive layer 204.

In some embodiments, the extension directions of the fourth grooves are parallel to the first direction X. The first metal structures include the third metal layers 219 and the fourth metal layers 220 respectively located in the plurality of the second grooves, and the third conductive layers 223 and the fourth conductive layers 222 respectively located in the plurality of the fourth grooves. The third metal layers 219 are located on the first metal layers 202, and the fourth metal layers 220 are located on the second metal layers 203. The third conductive layers 223 are located on the first conductive layer 205, and the fourth conductive layers 222 are located on the second conductive layer 204. The plurality of the fourth metal layers 220 are connected to the third conductive layers 223, and the plurality of the third metal layers 219 are connected to the fourth conductive layers 222. There are spacings between the third metal layers 219 and the third conductive layers 223, and there are spacings between the fourth metal layers 220 and the fourth conductive layers 222.

In some embodiments, the second plug structures include the first plugs 224 located on the first conductive layer 205 and the second plugs 221 located on the second conductive layer 204. The third metal layers 219 are electrically connected to the second metal layers 203 through the fourth conductive layers 222, the second plugs 221, and the second conductive layer 204. The fourth metal layers 220 are electrically connected to the first metal layers 202 through the third conductive layers 223, the first plugs 224, and the first conductive layer 205.

In some embodiments, the projections of the third metal layers 219 on the substrate 200 partially coincide with the projections of the first metal layers 202 on the substrate 200, and the projections of the fourth metal layers 220 on the substrate 200 partially coincide with the projections of the second metal layers 203 on the substrate 200.

In some embodiments, the projected images of the third grooves on the substrate 200 are rectangles.

In some embodiments, the sizes of the first grooves in the first direction X are smaller than side lengths of the projected images of the third grooves.

In some embodiments, the depths of the second grooves and the fourth grooves are the same.

In some embodiments, the sizes of the first grooves in the second direction Y are smaller than sizes of the second grooves in the second direction Y.

In some embodiments, the depths of the first grooves are 30% to 70% of the depths of the third grooves.

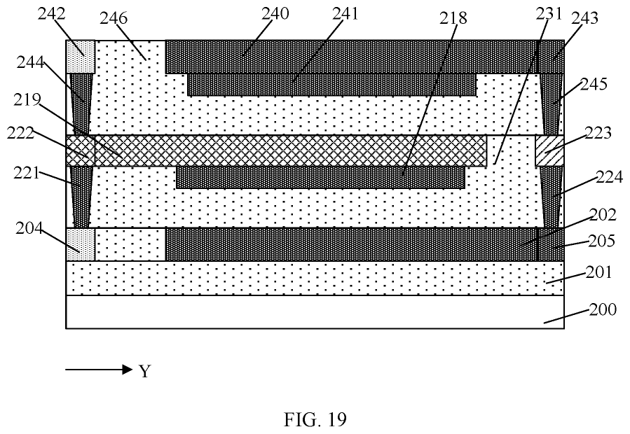

FIG. 19 illustrates a schematic view of another exemplary semiconductor structure consistent with various disclosed embodiments in the present disclosure.

Referring to FIG. 19 based on FIG. 18, second metal structures are further formed on the first metal structures. There are pluralities of the first metal structures and the second metal structures alternately arranged vertically in a direction perpendicular to the surface of the substrate 200.

The second metal structures include a plurality of fifth metal layers 240 and a plurality of sixth metal layers (not shown) that are alternately arranged in parallel along the first direction X, fifth conductive layers 243 located on the third conductive layers 223, sixth conductive layers 242 located on the fourth conductive layers 222, and second adhesion layers 241 located at the bottom of the fifth metal layers 240 and the sixth metal layers. The fifth metal layers 240 are located on the third metal layers 219, and the sixth metal layers are located on the fourth metal layers 220. The fifth conductive layers 243 and the sixth conductive layers 242 are parallel to the first direction X. The plurality of the fifth metal layers 240 are connected to the fifth conductive layers 243, and the plurality of the sixth metal layers are connected to the sixth conductive layers 242. There are spacings between the fifth metal layers 240 and the sixth conductive layers 242, and there are spacings between the sixth metal layers and the fifth conductive layers 243.

In some embodiments, third plugs 245 are further formed on the third conductive layers 223, and fourth plugs 244 are further formed on the fourth conductive layers 222. The fifth metal layers 240 are electrically connected to the fourth metal layers 220 through the fifth conductive layers 243, the third plugs 245, and the third conductive layers 223. The sixth metal layers are electrically connected to the third metal layers 219 through the sixth conductive layers 242, the fourth plugs 244, and the fourth conductive layers 222. Depths of the second adhesion layers 241 are smaller than depths of the third plugs 245 and the fourth plugs 244.

In some embodiments, sizes of the second adhesion layers 241 in the second direction Y are smaller than sizes of the fifth metal layers 240 and the sixth metal layers in the second direction Y.

In some embodiments, projections of the fifth metal layers 240 on the substrate 200 partially coincide with the projections of the third metal layers 219 on the substrate 200, and projections of the sixth metal layers on the substrate 200 partially coincide with the projections of the fourth metal layers 220 on the substrate 200.

In some embodiments, the second metal structures are located in a third dielectric layer 246.

A formation process of the second metal structures is the same as the formation process of the first metal structures, which will not be repeated herein.

The semiconductor structure has the first plug structures 218 at the bottom of the third metal layers 219 and the fourth metal layers 220, and has the second adhesion layers 241 at the bottom of the fifth metal layers 240 and the sixth metal layers. On one hand, the first plug structures 218 and the second adhesion layers 241 reduce spacings between the first metal structures, the bottom metal structure, and the second metal structures, so that capacitances between the first metal structures, the bottom metal structure, and the second metal structures increase. On the other hand, an overall cross-sectional area of the first plug structures 218 and the third metal layers 219 is increased, an overall cross-sectional area of the first plug structures 218 and the fourth metal layers 220 is increased, an overall cross-sectional area of the second adhesion layers 241 and the fifth metal layers 240 is increased, and an overall cross-sectional area of the second adhesion layers 241 and the sixth metal layers is increased, so that capacitance between the third metal layer 219 and the fourth metal layers 220 of the same layer increases, and capacitance between the fifth metal layer 240 and the sixth metal layer of the same layer increases, thereby an overall capacitance of the semiconductor structure increases.

Referring to FIG. 19 again, the present disclosure further provides a semiconductor structure different from the semiconductor structure shown in FIG. 18, which further includes the second metal structures located on the first metal structures. There are pluralities of the first metal structures and the second metal structures alternately arranged vertically in the direction perpendicular to the surface of the substrate. The second metal structures include the plurality of the fifth metal layers 240 and the plurality of the sixth metal layers that are alternately arranged in parallel along the first direction X, the fifth conductive layers 243 located on the third conductive layers 223, the sixth conductive layers 242 located on the fourth conductive layers 222, and the second adhesion layers 241 located at the bottom of the fifth metal layers 240 and the sixth metal layers. The fifth metal layers 240 are located on the third metal layers 219, and the sixth metal layers are located on the fourth metal layers 220. The fifth conductive layers 243 and the sixth conductive layers 242 are parallel to the first direction X. The plurality of the fifth metal layers 240 are connected to the fifth conductive layers 243, and the plurality of the sixth metal layers are connected to the sixth conductive layers 242. There are spacings between the fifth metal layers 240 and the sixth conductive layers 242, and there are spacings between the sixth metal layers and the fifth conductive layers 243.

In some embodiments, the semiconductor structure further includes the third plugs 245 located on the third conductive layers 223, and the fourth plugs 244 located on the fourth conductive layers 222. The fifth metal layers 240 are electrically connected to the fourth metal layers 220 through the fifth conductive layers 243, the third plugs 245, and the third conductive layers 223. The sixth metal layers are electrically connected to the third metal layers 219 through the sixth conductive layers 242, the fourth plugs 244, and the fourth conductive layers 222. The depths of the second adhesion layers 241 are smaller than the depths of the third plugs 245 and the fourth plugs 244.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

What is claimed is:

1. A semiconductor structure, comprising:
a substrate including a base, a device structure located on the base, and conductive layers located on the device structure;
a bottom metal structure located on the substrate, the bottom metal structure being electrically connected to the conductive layers;
a first dielectric layer located on the bottom metal structure, wherein the first dielectric layer contains:
a first opening structure including first grooves and second grooves on top of the first grooves, an extension direction of the first opening structure being parallel to an extension direction of the bottom metal structure, a projection of one of the first grooves on the substrate being located within a projection of one of the second grooves on the substrate, and bottoms of the first grooves exposing surface of the first dielectric layer;
a second opening structure including third grooves and fourth grooves on top of the third grooves, projections of a number of the third grooves on the substrate being located within a projection of one of the fourth grooves on the substrate, the third grooves exposing top surface of the bottom metal structure, and depths of the first grooves being smaller than depths of the third grooves;
first plug structures located in the first grooves;
second plug structures located in the third grooves; and
first metal structures located in the second grooves and the fourth grooves.

2. The semiconductor structure according to claim 1, wherein:
the substrate includes a first region and second regions located at two sides of the first region; and
the bottom metal structure includes:
a plurality of first metal layers and a plurality of second metal layers located on the first region; and
a first conductive layer and a second conductive layer respectively located on the second regions at two sides of the first region, wherein:
the plurality of the first metal layers and the plurality of the second metal layers are alternately arranged in parallel along a first direction parallel to a surface of the substrate;
the first conductive layer and the second conductive layer are parallel to the first direction;
the plurality of the first metal layers are connected to the first conductive layer, and the plurality of the second metal layers are connected to the second conductive layer;
spacings are between the first metal layers and the second conductive layer, and spacings are between the second metal layers and the first conductive layer;
the extension direction of the first opening structure is parallel to extension directions of the first metal layers and the second metal layers; and
the third grooves expose top surfaces of the second conductive layer and the first conductive layer.

3. The semiconductor structure according to claim 2, wherein:
the first opening structure is in a portion of the first dielectric layer that is on the first metal layers and the second metal layers; and
the second opening structure is in a portion of the first dielectric layer that is on the first conductive layer and the second conductive layer.

4. The semiconductor structure according to claim 2, wherein:
extension directions of the fourth grooves are parallel to the first direction;
the second plug structures include first plugs located on the first conductive layer and second plugs located on the second conductive layer; and
the first metal structures include:
third metal layers and fourth metal layers respectively located in a plurality of the second grooves; and
third conductive layers and fourth conductive layers respectively located in a plurality of the fourth grooves, wherein:
the third metal layers are located on the first metal layers, and the fourth metal layers are located on the second metal layers;
the third conductive layers are located on the first conductive layer, and the fourth conductive layers are located on the second conductive layer;
a plurality of the fourth metal layers are connected to the third conductive layers, and a plurality of the third metal layers are connected to the fourth conductive layers;
spacings are between the third metal layers and the third conductive layers, and spacings are between the fourth metal layers and the fourth conductive layers;
the third metal layers are electrically connected to the second metal layers through the fourth conductive layers, the second plugs, and the second conductive layer; and
the fourth metal layers are electrically connected to the first metal layers through the third conductive layers, the first plugs, and the first conductive layer.

5. The semiconductor structure according to claim 4, further comprising:
second metal structures located on the first metal structures including:
a plurality of fifth metal layers and a plurality of sixth metal layers alternately arranged in parallel along the first direction;
fifth conductive layers located on the third conductive layers;
sixth conductive layers located on the fourth conductive layers; and
second adhesion layers located at bottom of the fifth metal layers and the sixth metal layers, wherein:
there are pluralities of the first metal structures and the second metal structures alternately arranged vertically in a direction perpendicular to the surface of the substrate;
the fifth metal layers are located on the third metal layers, and the sixth metal layers are located on the fourth metal layers;
the fifth conductive layers and the sixth conductive layers are parallel to the first direction;
the plurality of the fifth metal layers are connected to the fifth conductive layers, and the plurality of the sixth metal layers are connected to the sixth conductive layers; and
spacings are between the fifth metal layers and the sixth conductive layers, and spacings are between the sixth metal layers and the fifth conductive layers.

6. The semiconductor structure according to claim 5, further comprising:
third plugs located on the third conductive layers; and
fourth plugs located on the fourth conductive layers, wherein:
the fifth metal layers are electrically connected to the fourth metal layers through the fifth conductive layers, the third plugs, and the third conductive layers;
the sixth metal layers are electrically connected to the third metal layers through the sixth conductive layers, the fourth plugs, and the fourth conductive layers;
depths of the second adhesion layers are smaller than depths of the third plugs and the fourth plugs;
projections of the fifth metal layers on the substrate partially coincide with the projections of the third metal layers on the substrate; and
projections of the sixth metal layers on the substrate partially coincide with the projections of the fourth metal layers on the substrate.

7. The semiconductor structure according to claim 1, wherein:
projected images of the third grooves on the substrate are rectangles; and
sizes of the first grooves in the first direction are smaller than side lengths of the projected images of the third grooves.

8. The semiconductor structure according to claim 1, wherein:
depths of the second grooves and the fourth grooves are the same;
sizes of the first grooves in a second direction are smaller than sizes of the second grooves in the second direction; and
the depths of the first grooves are 30% to 70% of the depths of the third grooves.

9. A method for fabricating a semiconductor structure, comprising:
providing a substrate including a base, a device structure located on the base, and conductive layers located on the device structure;
forming a bottom metal structure located on the substrate, the bottom metal structure being electrically connected to the conductive layers;
forming a first dielectric layer located on the bottom metal structure;
forming a first opening structure located in the first dielectric layer including first grooves and second grooves on top of the first grooves, an extension direction of the first opening structure being parallel to an extension direction of the bottom metal structure, projections of the first grooves on the substrate being located within projections of the second grooves on the substrate, and bottoms of the first grooves exposing surface of the first dielectric layer;
forming a second opening structure located in the first dielectric layer including third grooves and fourth grooves on top of the third grooves, projections of the third grooves on the substrate being located within projections of the fourth grooves on the substrate, the third grooves exposing top surface of the bottom metal structure, and depths of the first grooves being smaller than depths of the third grooves;
forming first plug structures located in the first grooves;
forming second plug structures located in the third grooves; and
forming first metal structures located in the second grooves and the fourth grooves.

10. The method for fabricating the semiconductor structure according to claim 9, wherein:
the substrate includes a first region and second regions located at two sides of the first region; and
the bottom metal structure includes:
a plurality of first metal layers and a plurality of second metal layers located on the first region; and
a first conductive layer and a second conductive layer respectively located on the second regions at two sides of the first region, wherein:
the plurality of the first metal layers and the plurality of the second metal layers are alternately arranged in parallel along a first direction parallel to surface of the substrate;
the first conductive layer and the second conductive layer are parallel to the first direction;
the plurality of the first metal layers are connected to the first conductive layer, and the plurality of the second metal layers are connected to the second conductive layer;
spacings are between the first metal layers and the second conductive layer, and spacings are between the second metal layers and the first conductive layer;
the extension direction of the first opening structure is parallel to extension directions of the first metal layers and the second metal layers; and
the third grooves expose top surfaces of the second conductive layer and the first conductive layer.

11. The method for fabricating the semiconductor structure according to claim 10, wherein:
the first opening structure is in a portion of the first dielectric layer that is on the first metal layers and the second metal layers; and
the second opening structure is in a portion of the first dielectric layer that is on the first conductive layer and the second conductive layer.

12. The method for fabricating the semiconductor structure according to claim 10, wherein:
extension directions of the fourth grooves are parallel to the first direction;
the second plug structures include first plugs located on the first conductive layer and second plugs located on the second conductive layer; and
the first metal structures include:
third metal layers and fourth metal layers respectively located in a plurality of the second grooves; and
third conductive layers and fourth conductive layers respectively located in a plurality of the fourth grooves, wherein:
the third metal layers are located on the first metal layers, and the fourth metal layers are located on the second metal layers;
the third conductive layers are located on the first conductive layer, and the fourth conductive layers are located on the second conductive layer;
a plurality of the fourth metal layers are connected to the third conductive layers, and a plurality of the third metal layers are connected to the fourth conductive layers;
spacings are between the third metal layers and the third conductive layers, and spacings are between the fourth metal layers and the fourth conductive layers;
the third metal layers are electrically connected to the second metal layers through the fourth conductive layers, the second plugs, and the second conductive layer; and
the fourth metal layers are electrically connected to the first metal layers through the third conductive layers, the first plugs, and the first conductive layer.

13. The method for fabricating the semiconductor structure according to claim 12, further comprising:
forming second metal structures located on the first metal structures including:
a plurality of fifth metal layers and a plurality of sixth metal layers alternately arranged in parallel along the first direction;
fifth conductive layers located on the third conductive layers;
sixth conductive layers located on the fourth conductive layers; and
second adhesion layers located at bottom of the fifth metal layers and the sixth metal layers, wherein:
there are pluralities of the first metal structures and the second metal structures alternately arranged vertically in a direction perpendicular to the surface of the substrate;
the fifth metal layers are located on the third metal layers, and the sixth metal layers are located on the fourth metal layers;
the fifth conductive layers and the sixth conductive layers are parallel to the first direction;
the plurality of the fifth metal layers are connected to the fifth conductive layers, and the plurality of the sixth metal layers are connected to the sixth conductive layers; and
spacings are between the fifth metal layers and the sixth conductive layers, and spacings are between the sixth metal layers and the fifth conductive layers.

14. The method for fabricating the semiconductor structure according to claim 13, further comprising:
forming third plugs located on the third conductive layers; and
forming fourth plugs located on the fourth conductive layers, wherein:
the fifth metal layers are electrically connected to the fourth metal layers through the fifth conductive layers, the third plugs, and the third conductive layers;
the sixth metal layers are electrically connected to the third metal layers through the sixth conductive layers, the fourth plugs, and the fourth conductive layers;
depths of the second adhesion layers are smaller than depths of the third plugs and the fourth plugs;
projections of the fifth metal layers on the substrate partially coincide with the projections of the third metal layers on the substrate; and
projections of the sixth metal layers on the substrate partially coincide with the projections of the fourth metal layers on the substrate.

15. The method for fabricating the semiconductor structure according to claim 9, wherein:
projected images of the third grooves on the substrate are rectangles; and
sizes of the first grooves in the first direction are smaller than side lengths of the projected images of the third grooves.

16. The method for fabricating the semiconductor structure according to claim 9, wherein:
depths of the second grooves and the fourth grooves are the same;
sizes of the first grooves in a second direction are smaller than sizes of the second grooves in the second direction; and
the depths of the first grooves are 20% to 80% of the depths of the third grooves.

17. The method for fabricating the semiconductor structure according to claim 9, wherein: and
the first opening structure and the second opening structure are formed simultaneously;
a method for fabricating the first opening structure and the second opening structure includes:
forming a first patterned layer on the first dielectric layer;
etching the first dielectric layer using the first patterned layer as a mask to form initial first grooves and initial third grooves in the first dielectric layer;
forming a second patterned layer on the first dielectric layer; and
etching the first dielectric layer using the second patterned layer as a mask to form the first grooves and the second grooves on the top of the first grooves, and to form the third grooves and the fourth grooves on the top of the third grooves in the first dielectric layer, wherein:
there are a plurality of third openings and fourth openings in the first patterned layer;
extension directions of the fourth openings are parallel to a second direction, the second direction being parallel to the surface of the substrate and being perpendicular to the first direction;
sizes of the fourth openings in the first direction are smaller than sizes of the third openings in the first direction and the second direction;
depths of the initial first grooves are smaller than depths of the initial third grooves;
there are fifth openings and sixth openings in the second patterned layer;
the fifth openings expose top surfaces of the initial third grooves and part of the surface of the first dielectric layer;
extension directions of the fifth openings are parallel to the first direction;
the sixth openings expose top surfaces of the initial first grooves and part of the surface of the first dielectric layer; and
extension directions of the sixth openings are parallel to the second direction.

18. The method for fabricating the semiconductor structure according to claim 17, wherein:
the sizes of the fourth openings in the first direction are smaller than the sizes of the third openings in the first direction and the second direction; and
the sizes of the fourth openings in the first direction are 30% to 70% of the sizes of the third openings in the first direction and the second direction.

19. The method for fabricating the semiconductor structure according to claim 17, wherein:
a process of etching the first dielectric layer using the first patterned layer as a mask includes a dry etching process; and
a process of etching the first dielectric layer using the second patterned layer as a mask includes a dry etching process.

20. The method for fabricating the semiconductor structure according to claim 9, wherein:
the first plug structures, the second plug structures, and the first metal structures are formed simultaneously; and
a method for fabricating the first plug structures, the second plug structures, and the first metal structures includes:
forming a metal material layer in the first grooves, the second grooves, the third grooves, the fourth grooves, and on the first dielectric layer; and
planarizing the metal material layer until top surface of the first dielectric layer is exposed to form the first plug structures, the second plug structures, and the first metal structures.
